(19) United States
(12) Patent Application Publication
(10) Pub. No.: US 2024/0063026 A1
(43) Pub. Date: Feb. 22, 2024

(54) ETCHING METHOD

(71) Applicant: Tokyo Electron Limited, Tokyo (JP)

(72) Inventors: Maju TOMURA, Miyagi (JP); Satoshi OHUCHIDA, Miyagi (JP)

(73) Assignee: Tokyo Electron Limited, Tokyo (JP)

(21) Appl. No.: 18/386,601

(22) Filed: Nov. 3, 2023

Related U.S. Application Data
(63) Continuation of application No. PCT/JP2021/017486, filed on May 7, 2021.

(51) Int. Cl. H01L 21/311; H01J 37/32

(52) U.S. Cl. CPC H01L 21/31116; H01J 37/32449; H01J 2237/334

(57) ABSTRACT

An etching method of the present disclosure includes preparing a substrate having a first region and a second region, the substrate including a multilayer film in which two or more types of silicon containing films are stacked in the first region, and a monolayer film formed from one type of silicon containing film in the second region, and etching the multilayer film and the monolayer film at the same time, in which in the etching, the multilayer film and the monolayer film are etched at the same time by plasma generated from a processing gas that contains a hydrogen fluoride gas, a phosphorus containing gas, and a carbon containing gas, a first recess having a first width is formed in the multilayer film, and a second recess having a second width wider than the first width is formed in the monolayer film.

### CROSS-REFERENCE AND PRIORITY INFORMATION

This application claims priority to PCT/JP2021/017486, filed May 7, 2021, the contents of which is incorporated by reference in its entirety.

### TECHNICAL FIELD

Exemplary embodiments of the present disclosure relate to an etching method.

### BACKGROUND ART

As a technique of etching a silicon containing film, there are etching methods described in Patent Literatures 1 and 2.

### CITATION LIST

### Patent Literature

PTL 1: US2016/0343580
PTL 2: JP2016-39310A

### SUMMARY OF INVENTION

### Technical Problem

The present disclosure provides an etching method for etching a multilayer film and a monolayer film each having a silicon containing film at the same time.

### Solution to Problem

In an exemplary embodiment of the present disclosure, an etching method is provided. The etching method includes a preparation step of preparing a substrate having a first region and a second region, the substrate including a multilayer film in which two or more types of silicon containing films are stacked in the first region, and a monolayer film formed from one type of silicon containing film in the second region, and an etching step of etching the multilayer film and the monolayer film at the same time, in which in the etching step, the multilayer film and the monolayer film are etched at the same time by plasma generated from a processing gas that contains a hydrogen fluoride gas, a phosphorus containing gas, and a carbon containing gas, a first recess having a first width is formed in the multilayer film, and a second recess having a second width wider than the first width is formed in the monolayer film.

In an exemplary embodiment of the present disclosure, an etching method is provided. The etching method includes a preparation step of preparing a substrate having a first region and a second region, the substrate including a multilayer film in which two or more types of silicon containing films are stacked in the first region, and a monolayer film formed from one type of silicon containing film in the second region, and an etching step of etching the multilayer film and the monolayer film at the same time, in which in the etching step, the multilayer film and the monolayer film are etched by plasma generated from a processing gas that contains a hydrogen fluoride gas, a phosphorus containing gas, and a carbon containing gas, a first recess is formed in the multilayer film, and a second recess is formed in the monolayer film.

In an exemplary embodiment of the present disclosure, an etching method is provided. The etching method includes a preparation step of preparing a substrate having a first region and a second region, the substrate including a multilayer film in which two or more types of silicon containing films are stacked in the first region, and a monolayer film formed from one type of silicon containing film in the second region, and an etching step of etching the multilayer film and the monolayer film at the same time, in which in the etching step, the multilayer film and the monolayer film are etched by plasma generated from a processing gas that contains a phosphorus containing gas, a fluorine containing gas, a hydrofluorocarbon gas, and a halogen containing gas that contains a halogen element other than fluorine, a first recess having a first width is formed in the multilayer film, and a second recess having a second width wider than the first width is formed in the monolayer film.

In an exemplary embodiment of the present disclosure, an etching method is provided. The etching method includes a preparation step of preparing a substrate having a first region and a second region, the substrate including a multilayer film in which two or more types of silicon containing films are stacked in the first region, and a monolayer film formed from one type of silicon containing film in the second region, and an etching step of etching the multilayer film and the monolayer film at the same time, in which in the etching step, the multilayer film and the monolayer film are etched by plasma generated from a processing gas that contains a phosphorus containing gas, a fluorine containing gas, a hydrofluorocarbon gas, and a halogen containing gas that contains a halogen element other than fluorine, a first recess is formed in the multilayer film, and a second recess is formed in the monolayer film.

In an exemplary embodiment of the present disclosure, an etching method is provided. The etching method includes a preparation step of preparing a substrate having a first region and a second region, the substrate including a multilayer film in which two or more types of silicon containing films are stacked in the first region, and a monolayer film formed from one type of silicon containing film in the second region, a first etching step of etching the multilayer film and the monolayer film at the same time, and a second etching step of etching at least one of the multilayer film and the monolayer film, in which in the first etching step, the multilayer film and the monolayer film are etched by plasma generated from a first processing gas that contains a hydrogen fluoride gas and a phosphorus containing gas, a first recess is formed in the multilayer film, and a second recess is formed in the monolayer film, and in the second etching step, the multilayer film and the monolayer film are etched by plasma generated from a second processing gas that contains a hydrogen fluoride gas and a phosphorus containing gas, a third recess is formed in at least one of the multilayer film and the monolayer film, and a flow rate of the phosphorus containing gas contained in the first processing gas is different from a flow rate of the phosphorus containing gas contained in the second processing gas.

### Advantageous Effects of Invention

According to one exemplary embodiment of the present disclosure, it is possible to etch a multilayer film and a monolayer film each having a silicon containing film at the same time.

### BRIEF DESCRIPTION OF DRAWINGS

FIG. 1 is a diagram schematically showing a plasma processing apparatus according to an exemplary embodiment.

FIG. 2 is a flowchart of an etching method according to the exemplary embodiment.

FIG. 3 is a top diagram showing an example of a substrate W prepared in step ST1.

FIG. 4 is a diagram showing a part of the AA′ cross-section of the substrate W illustrated in FIG. 3.

FIG. 5 is a diagram showing a cross-sectional structure of the substrate W etched in step ST2.

FIG. 6 is a graph showing the relationship between the flow rate of the PF₃ and the etching rates of a multilayer film ML and a monolayer film SL.

### DESCRIPTION OF EMBODIMENTS

Hereinafter, embodiments of the present disclosure will be described.

In an exemplary embodiment, an etching method is provided.

The etching method includes a preparation step of preparing a substrate having a first region and a second region, the substrate including a multilayer film in which two or more types of silicon containing films are stacked in the first region, and a monolayer film formed from one type of silicon containing film in the second region, and an etching step of etching the multilayer film and the monolayer film at the same time, in which in the etching step, the multilayer film and the monolayer film are etched at the same time by plasma generated from a processing gas that contains a hydrogen fluoride gas, a phosphorus containing gas, and a carbon containing gas, a first recess having a first width is formed in the multilayer film, and a second recess having a second width wider than the first width is formed in the monolayer film.

The etching method includes a preparation step of preparing a substrate having a first region and a second region, the substrate including a multilayer film in which two or more types of silicon containing films are stacked in the first region, and a monolayer film formed from one type of silicon containing film in the second region, and an etching step of etching the multilayer film and the monolayer film at the same time, in which in the etching step, the multilayer film and the monolayer film are etched by plasma generated from a processing gas that contains a hydrogen fluoride gas, a phosphorus containing gas, and a carbon containing gas, a first recess is formed in the multilayer film, and a second recess is formed in the monolayer film.

The etching method includes a preparation step of preparing a substrate having a first region and a second region, the substrate including a multilayer film in which two or more types of silicon containing films are stacked in the first region, and a monolayer film formed from one type of silicon containing film in the second region, and an etching step of etching the multilayer film and the monolayer film at the same time, in which in the etching step, the multilayer film and the monolayer film are etched by plasma generated from a processing gas that contains a phosphorus containing gas, a fluorine containing gas, a hydrofluorocarbon gas, and a halogen containing gas that contains a halogen element other than fluorine, a first recess having a first width is formed in the multilayer film, and a second recess having a second width wider than the first width is formed in the monolayer film.

The etching method includes a preparation step of preparing a substrate having a first region and a second region, the substrate including a multilayer film in which two or more types of silicon containing films are stacked in the first region, and a monolayer film formed from one type of silicon containing film in the second region, and an etching step of etching the multilayer film and the monolayer film at the same time, in which in the etching step, the multilayer film and the monolayer film are etched by plasma generated from a processing gas that contains a phosphorus containing gas, a fluorine containing gas, a hydrofluorocarbon gas, and a halogen containing gas that contains a halogen element other than fluorine, a first recess is formed in the multilayer film, and a second recess is formed in the monolayer film.

In one exemplary embodiment, the substrate includes a mask film provided on the multilayer film and the monolayer film, the mask film having a first side wall defining a first opening on the multilayer film, and a second side wall defining a second opening on the monolayer film, and in the etching step, the first recess is formed by etching the multilayer film with the plasma in the first opening, and the second recess is formed by etching the monolayer film with the plasma in the second opening.

In one exemplary embodiment, one of the first recess and the second recess is a hole, and the other of the first recess and the second recess is a slit.

In one exemplary embodiment, the two or more types of silicon containing films include a silicon oxide film and a silicon nitride film, and the one type of silicon containing film is a silicon oxide film.

In one exemplary embodiment, the phosphorus containing gas is a halogenated phosphorus gas.

In one exemplary embodiment, the carbon containing gas is a hydrocarbon gas, a fluorocarbon gas, or a hydrofluorocarbon gas.

The etching method includes a preparation step of preparing a substrate having a first region and a second region, the substrate including a multilayer film in which two or more types of silicon containing films are stacked in the first region, and a monolayer film formed from one type of silicon containing film in the second region, a first etching step of etching the multilayer film and the monolayer film at the same time, and a second etching step of etching one of the multilayer film and the monolayer film, in which in the first etching step, the multilayer film and the monolayer film are etched by plasma generated from a first processing gas that contains a hydrogen fluoride gas and a phosphorus containing gas, a first recess is formed in the multilayer film, a second recess is formed in the monolayer film, and in the second etching step, the multilayer film and the monolayer film are etched by plasma generated from a second processing gas that contains a hydrogen fluoride gas and a phosphorus containing gas, a third recess is formed in one of the multilayer film and the monolayer film, and a flow rate of the phosphorus containing gas contained in the first processing gas is different from a flow rate of the phosphorus containing gas contained in the second processing gas.

In one exemplary embodiment, a second etching step is executed after a first etching step is executed.

In one exemplary embodiment, the first etching step is executed after the second etching step is executed.

In one exemplary embodiment, in the first etching step, a plurality of memory holes in which the plurality of memory cells are formed are formed in the multilayer film as the first recess, and a plurality of contact holes in which the plurality of contacts are formed are formed in the monolayer film as the second recess, and in the second etching step, slits extending from the first region to the second region are formed in the multilayer film and the monolayer film as the third recess.

In one exemplary embodiment, in the first etching step, a plurality of memory holes in which the plurality of memory cells are formed are formed in the multilayer film as the first recess, and slits extending from the first region to the second region are formed in the multilayer film and the monolayer film as the first recess and the second recess, and in the second etching step, a plurality of contact holes in which the plurality of contacts are formed are formed in the monolayer film as the second recess.

In one exemplary embodiment, in the first etching step, a plurality of contact holes in which the plurality of contacts are formed are formed in the monolayer film as the second recess, and slits extending from the first region to the second region are formed in the multilayer film and the monolayer film as the first recess and the second recess, and in the second etching step, a plurality of memory holes in which the plurality of memory cells are formed are formed in the multilayer film as the first recess.

In one exemplary embodiment, in the first etching step, slits extending from the first region to the second region are formed in the multilayer film and the monolayer film as the first recess and the second recess, and in the second etching step, a plurality of memory holes in which the plurality of memory cells are formed are formed in the multilayer film as the first recess, and a plurality of contact holes in which the plurality of contacts are formed are formed in the monolayer film as the second recess.

Hereinafter, each embodiment of the present disclosure will be described in detail with reference to the drawings. In the drawings, the same or similar elements are denoted by the same reference numerals, and overlapping descriptions thereof will be omitted. Unless otherwise specified, a positional relationship of up/down, left/right, or the like will be described based on a positional relationship illustrated in the drawings. The dimensional ratios in the drawings do not indicate actual ratios, and the actual ratios are not limited to the illustrated ratios.

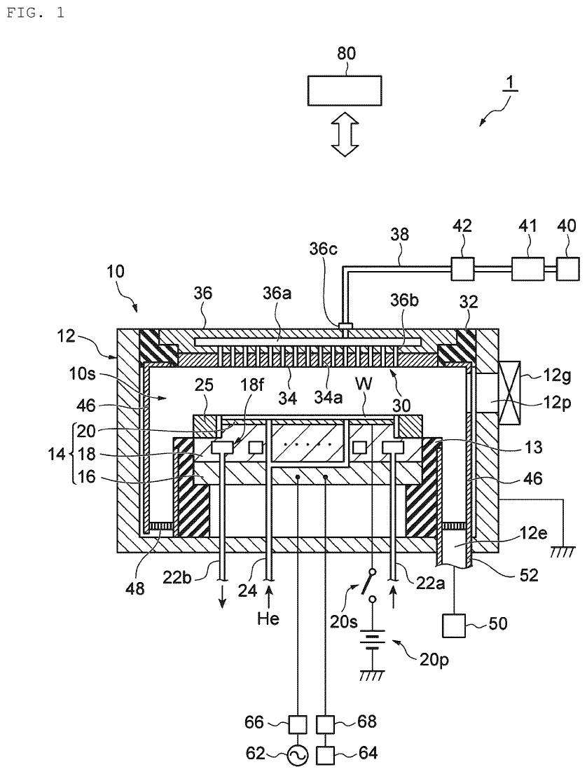

FIG. 1 is a diagram schematically showing a plasma processing apparatus according to an exemplary embodiment. A plasma processing apparatus 1 shown in FIG. 1 includes a chamber 10. The chamber 10 has an internal space 10s therein. The chamber 10 includes a chamber body 12. The chamber body 12 has a substantially cylindrical shape. The chamber body 12 is made of, for example, aluminum. A film having corrosion resistance is provided on the inner wall surface of the chamber body 12. The film having corrosion resistance may be formed of ceramic such as aluminum oxide or yttrium oxide.

The chamber body 12 has a side wall having a port 12p. The substrate W is transferred between the internal space 10s and the outside of the chamber 10 through the port 12p. The port 12p is opened and closed by a gate valve 12g. The gate valve 12g is provided along the side wall of the chamber body 12.

A support 13 is provided on the bottom of the chamber body 12. The support 13 is formed of an insulating material. The support 13 has a substantially cylindrical shape. The support 13 extends upward from the bottom of the chamber body 12 in the internal space 10s. The support 13 supports a substrate support 14. The substrate support 14 is configured to support the substrate W in the internal space 10s.

The substrate support 14 includes a lower electrode 18 and an electrostatic chuck 20. The substrate support 14 may include an electrode plate 16. The electrode plate 16 is substantially disk-shaped and is formed of a conductor such as aluminum. The lower electrode 18 is provided on the electrode plate 16. The lower electrode 18 is substantially disk-shaped and is formed of a conductor such as aluminum. The lower electrode 18 is electrically connected to the electrode plate 16.

The electrostatic chuck 20 is provided on the lower electrode 18. The substrate W is placed on the upper surface of the electrostatic chuck 20. The electrostatic chuck 20 has a main body and an electrode. The main body of the electrostatic chuck 20 is substantially disc-shaped and is formed of a dielectric. The electrode of the electrostatic chuck 20 is an electrode having a film shape, and is provided in the main body of the electrostatic chuck 20. The electrode of the electrostatic chuck 20 is connected to a direct-current power supply 20p through a switch 20s. When the voltage from the direct-current power supply 20p is applied to the electrode of the electrostatic chuck 20, an electrostatic attraction force is generated between the electrostatic chuck 20 and the substrate W. The substrate W is attracted to the electrostatic chuck 20 by an electrostatic attraction force thereof and held by the electrostatic chuck 20.

An edge ring 25 is disposed onto the substrate support 14. The edge ring 25 is a ring-shaped member. The edge ring 25 may be formed of silicon, silicon carbide, or quartz. The substrate W is disposed on the electrostatic chuck 20 and within the region surrounded by the edge ring 25.

A flow path 18f is provided in the interior of the lower electrode 18. A heat exchange medium (for example, a refrigerant) is supplied from a chiller unit provided outside the chamber 10 to the flow path 18f through a pipe 22a. The heat exchange medium supplied to the flow path 18f is returned to the chiller unit via a pipe 22b. In the plasma processing apparatus 1, the temperature of the substrate W placed on the electrostatic chuck 20 is adjusted by heat exchange between the heat exchange medium and the lower electrode 18.

The plasma processing apparatus 1 is provided with a gas supply line 24. The gas supply line 24 supplies a heat transfer gas (e.g., He gas) from a heat transfer gas supply mechanism to a gap between the upper surface of the electrostatic chuck 20 and the back surface of the substrate W.

The plasma processing apparatus 1 further includes an upper electrode 30. The upper electrode 30 is provided above the substrate support 14. The upper electrode 30 is supported on an upper portion of the chamber body 12 through a member 32. The member 32 is formed of 9 materials having insulation properties. The upper electrode 30 and the member 32 close the upper opening of the chamber body 12.

The upper electrode 30 may include a top plate 34 and a support body 36. The lower surface of the ceiling plate 34 is a lower surface on the internal space 10s side and defines the internal space 10s. The ceiling plate 34 may be formed of a low resistance conductor or semiconductor that generates little Joule heat. The ceiling plate 34 includes a plurality of gas ejection holes 34a which penetrate the ceiling plate 34 in a plate thickness direction thereof.

The support 36 detachably supports the ceiling plate 34. The support body 36 is formed of a conductive material such as aluminum. A gas diffusion chamber 36a is provided in the interior of the support 36. The support body 36 includes a plurality of gas holes 36b extending downward from the gas diffusion chamber 36a. The plurality of gas holes 36b communicate with the plurality of gas ejection holes 34a, respectively. The support body 36 has a gas introduction port 36c. The gas introduction port 36c is connected to the gas diffusion chamber 36a. A gas supply pipe 38 is connected to the gas introduction port 36c.

A gas source group 40 is connected to the gas supply pipe 38 through a flow rate controller group 41 and a valve group 42. The flow rate controller group 41 and the valve group 42 constitute a gas supply. The gas supply may further include the gas source group 40. The gas source group 40 includes a plurality of gas sources. The plurality of gas sources include sources of processing gases used in the present etching method. The flow rate controller group 41 includes a plurality of flow rate controllers. Each of the plurality of flow rate controllers of the flow rate controller group 41 is a mass flow controller or a pressure control type flow rate controller. The valve group 42 includes a plurality of opening/closing valves. Each of the plurality of gas sources of the gas source group 40 is connected to the gas supply pipe 38 through a corresponding flow rate controller of the flow rate controller group 41 and a corresponding opening/closing valve of the valve group 42.

In the plasma processing apparatus 1, a shield 46 is detachably provided along the inner wall surface of the chamber body 12 and the outer periphery of the support 13. The shield 46 prevents reaction by-products from adhering to the chamber body 12. The shield 46 is configured, for example, by forming a film having corrosion resistance on the surface of a base material made of aluminum. The film having corrosion resistance may be formed of ceramic such as yttrium oxide.

A baffle plate 48 is located between the support 13 and the side wall of the chamber body 12. The baffle plate 48 is configured, for example, by forming a film having corrosion resistance (such as yttrium oxide) on the surface of a member formed of aluminum. A plurality of through-holes are formed in the baffle plate 48. An exhaust port 12e is provided below the baffle plate 48 and in the bottom of the chamber body 12. An exhaust device 50 is connected to the exhaust port 12e via an exhaust pipe 52. The exhaust device 50 includes a pressure adjusting valve and a vacuum pump such as a turbo molecular pump.

The plasma processing apparatus 1 is coupled to a radio-frequency power supply 62 and a bias power supply 64. The radio-frequency power supply 62 is a power supply that generates a radio-frequency power HF. The radio-frequency power HF has a first frequency suitable for the generation of plasma. The first frequency is, for example, a frequency in the range of 27 MHz to 100 MHz. The radio-frequency power supply 62 is connected to the lower electrode 18 via a matcher 66 and the electrode plate 16. The matcher 66 includes a circuit for matching the impedance on the load side (lower electrode 18 side) of the radio-frequency power supply 62 with the output impedance of the radio-frequency power supply 62. The radio-frequency power supply 62 may be connected to the upper electrode 30 via the matcher 66. The radio-frequency power supply 62 constitutes an example of a plasma generator.

The bias power supply 64 is a power supply that generates an electric bias. The bias power supply 64 is electrically connected to the lower electrode 18. The electric bias has a second frequency. The second frequency is lower than the first frequency. The second frequency is, for example, a frequency in the range of 400 kHz to 13.56 MHz. The electric bias is supplied to the substrate support 14 for drawing ions to the substrate W when used together with the radio-frequency power HF. In an example, an electric bias is supplied to the lower electrode 18. When an electric bias is supplied to the lower electrode 18, the potential of the substrate W placed on the substrate support 14 varies in a cycle defined with the second frequency. An electric bias may be supplied to the bias electrode provided in the electrostatic chuck 20.

In one embodiment, the electric bias may be a radio-frequency power LF having the second frequency. The radio-frequency power LF is used as radio-frequency bias power for drawing ions into the substrate W when used together with the radio-frequency power HF. The bias power supply 64 configured to generate the radio-frequency power LF is connected to the lower electrode 18 through the matcher 68 and the electrode plate 16. The matcher 68 includes a circuit for matching the impedance on the load side (lower electrode 18 side) of the bias power supply 64 with the output impedance of the bias power supply 64.

Plasma may be generated by using the radio-frequency power LF instead of the radio-frequency power HF, that is, by using only a single radio-frequency power. In this case, the frequency of the radio-frequency power LF may be larger than 13.56 MHz, for example 40 MHz. In addition, in this case, the plasma processing apparatus 1 does not need to include the radio-frequency power supply 62 and the matcher 66. In this case, the bias power supply 64 constitutes an example of a plasma generator.

In another embodiment, the electric bias may be a pulsed voltage. In this case, the bias power supply may be a direct-current power supply. The bias power supply may be configured such that the power supply itself supplies a pulsed voltage, and may be configured such that a device for pulsing the voltage is provided downstream of the bias power supply. In an example, the pulsed voltage is supplied to the lower electrode 18 such that a negative potential is generated at the substrate W. The pulsed voltage may be a rectangular wave, may be a triangular wave, may be an impulse, or may have any other waveform.

The cycle of the pulsed voltage is defined with the second frequency. The cycle of the pulsed voltage includes two periods. The pulsed voltage in one of the two periods is a negative voltage. The level (that is, absolute value) of the voltage in one of the two periods is higher than the level (that is absolute value) of the voltage in the other of the two periods. The voltage in the other period may be either negative or positive. The level of the negative voltage in the other period may be larger than zero (0) or may be zero (0). In this embodiment, the bias power supply 64 is connected to the lower electrode 18 through a low-pass filter and the electrode plate 16. The bias power supply 64 may be connected to a bias electrode provided in the electrostatic chuck 20, instead of the lower electrode 18.

In one embodiment, the bias power supply 64 may supply a continuous wave of an electric bias to the lower electrode 18. That is, the bias power supply 64 may continuously supply an electric bias to the lower electrode 18.

In another embodiment, the bias power supply 64 may supply a pulsed wave of an electric bias to the lower electrode 18. The pulsed wave of the electric bias may be periodically supplied to the lower electrode 18. The cycle of the pulsed wave of the electric bias is defined with a third frequency. The third frequency is lower than the second frequency. The third frequency is, for example, 1 Hz or more and 200 kHz or less. In another example, the third frequency may be 5 Hz or more and 100 kHz or less.

The cycle of the pulsed wave of the electric bias includes two periods, that is, an H period and an L period. The level of the electric bias in the H period (that is, the level of the pulse of the electric bias) is higher than the level of the electric bias in the L period. That is, the pulsed wave of the electric bias may be supplied to the lower electrode 18 by increasing or decreasing the level of the electric bias. The level of the electric bias in the L period may be larger than zero (0). Alternatively, the level of the electric bias in the L period may be zero (0). That is, the pulsed wave of the electric bias may be supplied to the lower electrode 18 by alternately switching between the supply and the stop of the supply of the electric bias to the lower electrode 18. Here, when the electric bias is the radio-frequency power LF, the level of the electric bias is the power level of the radio-frequency power LF. When the electric bias is the radio-frequency power LF, the level of the radio-frequency power LF in the pulse of the electric bias may be 2 kW or more. When the electric bias is a pulsed wave of a negative direct-current voltage, the level of the electric bias is the effective value of the absolute value of the negative direct-current voltage. The duty ratio of the pulsed wave of the electric bias, that is, the ratio occupied by the H period in the cycle of the pulsed wave of the electric bias is, for example, 1% or more and 80% or less. In another example, the duty ratio of the pulsed wave of the electric bias may be 5% or more and 50% or less. Alternatively, the duty ratio of the pulsed wave of the electric bias may be 50% or more and 99% or less.

In one embodiment, the radio-frequency power supply 62 may supply a continuous wave of the radio-frequency power HF. That is, the radio-frequency power supply 62 may continuously supply the radio-frequency power HF.

In another embodiment, the radio-frequency power supply 62 may supply the pulsed wave of the radio-frequency power HE The pulsed wave of the radio-frequency power HF may be periodically supplied. The cycle of the pulsed wave of the radio-frequency power HF is defined with a fourth frequency. The fourth frequency is lower than the second frequency. In an embodiment, the fourth frequency is the same as the third frequency. The cycle of the pulsed wave of the radio-frequency power HF includes two periods, that is, the H period and the L period. The power level of the radio-frequency power HF in the H period is higher than the power level of the radio-frequency power HF in the L period of the two periods. The power level of the radio-frequency power HF in the L period may be larger than zero (0) or may be zero (0).

The cycle of the pulsed wave of the radio-frequency power HF may be synchronized with the cycle of the pulsed wave of the electric bias. The H period in the cycle of the pulsed wave of the radio-frequency power HF may be synchronized with the H period in the cycle of the pulsed wave of the electric bias. Alternatively, the H period in the cycle of the pulsed wave of the radio-frequency power HF may not be synchronized with the H period in the cycle of the pulsed wave of the electric bias. The time length of the H period in the cycle of the pulsed wave of the radio-frequency power HF may be the same as or different from the time length of the H period in the cycle of the pulsed wave of the electric bias.

When plasma processing is performed in the plasma processing apparatus 1, a gas is supplied from the gas supply to the internal space 10s. Further, by supplying the radio-frequency power HF and/or the electric bias, a radio-frequency electric field is generated between the upper electrode 30 and the lower electrode 18. The generated radio-frequency electric field generates plasma from the gas in the internal space 10s.

The plasma processing apparatus 1 may further include a controller 80. The controller 80 may be a computer including a processor, a storage unit such as a memory, an input device, a display device, a signal input/output interface, and the like. The controller 80 controls each part of the plasma processing apparatus 1. The controller 80 may allow an operator to perform an input operation of a command in order to manage the plasma processing apparatus 1 using an input device. Further, the controller 80 may visualize and display an operating status of the plasma processing apparatus 1 by a display device. Further, a control program and recipe data are stored in the storage unit. The control program is performed by the processor in order to perform various kinds of processing in the plasma processing apparatus 1. The processor executes the control program and controls each part of the plasma processing apparatus 1 in accordance with the recipe data.

The plasma formed in the plasma processing space may be capacitively coupled plasma (CCP), inductively coupled plasma (ICP), electron-cyclotron-resonance plasma (ECR plasma), Helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 200 kHz to 150 MHz.

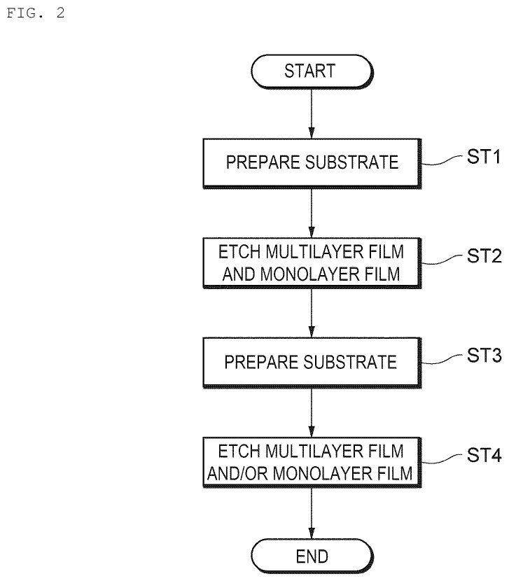

FIG. 2 is a flowchart showing an etching method (hereinafter, also referred to as “the present etching method”) according to one exemplary embodiment. The present etching method includes a preparation step (ST1) of preparing a substrate, and an etching step (ST2) for etching a multilayer film and a monolayer film provided in the substrate. Further, the present etching method may further include step (ST3) of preparing a substrate and step (ST4) of etching a multilayer film and/or a monolayer film. When the present etching method includes step ST3 and step ST4, step ST1 and step ST2 may be performed after step ST3 and step ST4 are executed. Further, the present etching method is performed on a substrate using, for example, the plasma processing apparatus 1 shown in FIG. 1.

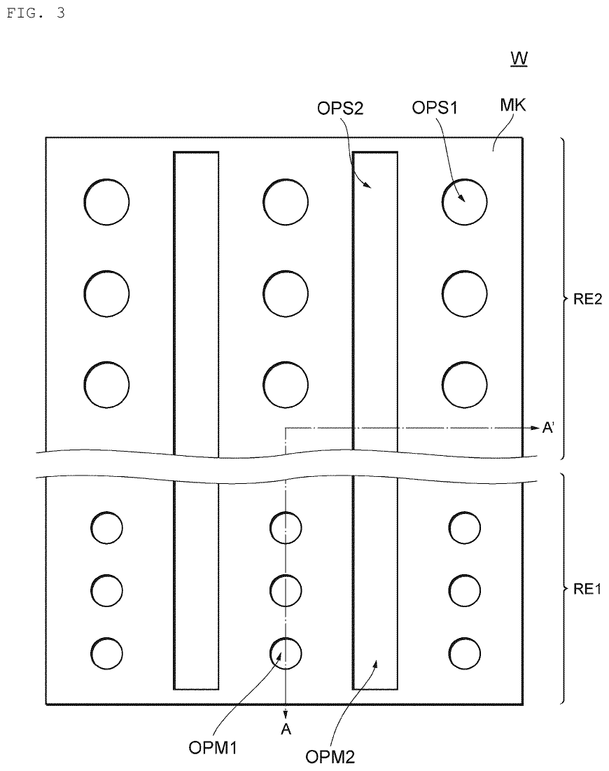

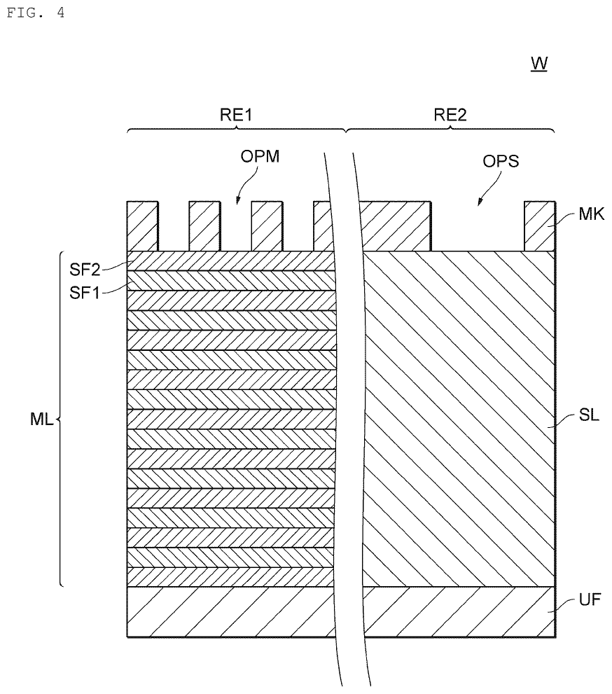

FIG. 3 is a top diagram showing an example of the substrate W prepared in step ST1. FIG. 4 is a diagram showing a part of the AA′ cross-section of the substrate W illustrated in FIG. 3. The substrate W may be used for manufacturing a semiconductor device including a semiconductor memory device such as a DRAM or a 3D-NAND flash memory.

The substrate W has a first region RE1 and a second region RE2. In a plan diagram (top diagram of FIG. 3) of the substrate W, the first region RE1 and the second region RE2 are regions each having a predetermined range on the substrate W. The first region RE1 and the second region RE2 may be two regions adjacent to each other, or may be two regions apart from each other. The first region RET may be, for example, a memory cell region in a semiconductor memory device. Further, the second region RE2 may be, for example, a contact region or a peripheral circuit region in a semiconductor memory device. In an example, the contact region is a region where one or more contact holes for electrically connecting one or more memory cells and a peripheral circuit are provided.

The substrate W includes an underlying film UF provided from the first region RET to the second region RE2. Further, the substrate W includes the multilayer film ML provided on the underlying film UF in the first region RET. The multilayer film ML is a stacked film in which two or more types of silicon containing films are stacked. In the present embodiment, the multilayer film ML is a stacked film in which a silicon nitride film SF1 and a silicon oxide film SF2 are alternately and repeatedly stacked.

Further, the substrate W includes the monolayer film SL provided on the underlying film UF in the second region RE2. The monolayer film SL is, for example, a film made of a silicon containing film such as a silicon oxide film or a silicon nitride film. In the present embodiment, the monolayer film SL is a silicon oxide film. The multilayer film ML and the monolayer film SL may have the same thickness or different thicknesses.

The substrate W further includes a mask film MK. The mask film MK is provided on the multilayer film ML and the monolayer film SL. That is, the mask film MK is provided from the first region RET to the second region RE2. The mask film MK has a predetermined pattern. In the mask film MK, one or more openings OPM are provided in the first region RET (the circular opening provided in the first region RET is also referred to as an opening OPM1, and the rectangular slit (opening) is also referred to as an opening OPM2). In the present embodiment, each of the one or more openings OPM is an opening defined by side walls formed in the mask film MK. Further, in the mask film MK, one or more openings OPS are provided in the second region RE2 (the circular opening provided in the second region RE2 is also referred to as an opening OPS1, and the rectangular slit (opening) is also referred to as an opening OPS2). In the present embodiment, the one or more openings OPS are openings defined by side walls formed in the mask film MK.

In an example, the openings OPM and OPS are openings for forming holes, contact holes, line-and-spaces, slits, trenches, and the like in which memory cells are formed, in the multilayer film ML and/or the monolayer film SL. In an example, the opening OPM and the opening OPS have shapes such as a circular shape, an elliptical shape, a linear shape, and a rectangular shape in a plan diagram. The opening OPM and the opening OPS may have the same shape or different shapes in a plan diagram. The opening OPS may have a wider width than the opening OPM (for example, a diameter of a circular opening, a short diameter of an elliptical opening, a line width of a linear opening, and a length of a short side or a long side of a rectangular opening). Further, the opening OPM and the opening OPS may be an integrally formed opening. As an example, the opening OPM and the opening OPS may be a part of one slit formed from the first region RET to the second region RE2.

In the present embodiment, as shown in FIG. 3, as an example, a plurality of openings OPM1 having a circular shape in a plan diagram are provided in the first region RET of the mask film MK. Further, a plurality of openings OPS1 having a circular shape in a plan diagram are provided in the second region RE2 of the mask film MK. As an example, the width (diameter) of the opening OPM1 provided in the first region RET is smaller than the width (diameter) of the opening OPM1 provided in the second region RE2. The width (diameter) of the opening OPM1 may be larger than the width (diameter) of the opening OPS2, or may be the same as the width (diameter) of the opening OPS2.

Further, in the present embodiment, as shown in FIG. 3, an opening having a slit shape in a plan diagram is provided from the first region RET to the second region RE2 of the mask film MK. The opening includes an opening OPM2, which is a portion provided in the first region RET of the mask film MK, and an opening OPS2, which is a portion provided in the second region RE2. The widths of the opening OPM2 and the opening OPS2 may be wider or narrower than the width (diameter) of the opening OPM1 and/or the opening OPS1, and may be the same as the width (diameter) of the opening OPM1 and/or the opening OPS1. Further, the width of the opening OPM2 may be different from the width of the opening OPS2. Further, the opening having the slit shape in FIG. 3 may be provided only in either the first region RET or the second region RE2. That is, the opening may be a slit having only one of the opening OPM2 and the opening OPS2.

The mask film MK is formed of a material having an etching rate lower than the etching rates of the multilayer film ML and the monolayer film SL in step ST2. The mask film MK may be formed of an organic material. The mask film MK may be, for example, an amorphous carbon film, a photoresist film, or an SOC film (spin-on carbon film). The mask film MK may be a metal containing mask formed of a metal containing material such as titanium nitride, tungsten, or tungsten carbide.

Hereinafter, an example in which the present etching method illustrated in FIG. 2 is executed on the substrate W in the plasma processing apparatus 1 will be described with reference to each drawing. In the present example, the controller 80 controls each part of the plasma processing apparatus 1 so that the present etching method is executed in the plasma processing apparatus 1.

### (Step ST1: Preparation of Substrate W)

In step ST1, the substrate W is prepared in the internal space 10s of the chamber 10. At least a part of the process of forming each configuration of the substrate W illustrated in FIGS. 3 and 4 may be performed in the internal space 10s. Further, after all or a part of each configuration of the substrate W is formed by a device or a chamber outside the plasma processing apparatus 1, the substrate W may be loaded into the internal space 10s and placed on the electrostatic chuck 20.

### (Step ST2: Etching of Multilayer Film ML and Monolayer Film SL)

Next, in step ST2, the multilayer film ML and the monolayer film SL are etched. Step ST2 is an example of a first etching step. First, a processing gas for generating plasma is supplied into the chamber 10. The processing gas includes a gas species that generates an HF species. The gas species that generates an HF species may include, for example, an HF gas (hydrogen fluoride gas). The gas species that generates an HF species may be, in other examples, H₂ and CₓF_{y} (x and y are natural numbers), H₂ and CₛHₜFᵤ, and CₛHₜFᵤ(s, t, and u are natural numbers) alone. Further, the processing gas may contain a gas that contains fluorine or another halogen element, in addition to the gas that generates the HF species. The processing gas may contain at least one halogen containing molecule. The processing gas may contain at least one of fluorocarbon or hydrofluorocarbon as at least one halogen containing molecule. The fluorocarbon is, for example, at least one of CF₄, C₃F₈, C₄F₆, or C₄F₈. The hydrofluorocarbon is, for example, at least one of CH₂F₂, CHF₃, or CH₃F. The hydrofluorocarbon may contain two or more carbons. Further, the hydrofluorocarbon may contain three carbons or four carbons. The hydrofluorocarbon may be, for an example, at least one selected from the group consisting of C₂HF₅, C₂H₂F₄, C₂H₃F₃, C₂H₄F₂, C₃HF₇, C₃H₂F₂, C₃H₂F₆, C₃H₂F₄, C₃H₃F₅, C₄H₅F₅, C₄H₂F₆, C₅H₂F₁₀ and c-C₅H₃F₇. In an example, the carbon containing gas is at least one selected from the group consisting of C₄F₈, C₃H₂F₄, and C₄H₂F₆. Further, the halogen containing molecule may not contain carbon. The halogen containing molecules are, for example, a nitrogen trifluoride gas (NF₃ gas) or a sulfur hexafluoride gas (SF6 gas). Further, the processing gas may further contain a halogen containing gas containing a halogen element other than fluorine. The halogen containing gas is, for example, at least one selected from the group consisting of Cl₂, SiH₂Cl₂, SiCl₄, Si₂Cl₆, CHCl₃, CCl₄, and BCl₃. The halogen containing gas may be, for example, HBr or NF₃. When an HF gas is used, a carbon containing gas may be included. The carbon containing gas can form a carbon containing deposition on the mask to protect the mask from the etching.

The processing gas used in step ST2 may further contain at least one phosphorus containing molecule. The phosphorus containing molecule may be an oxide, such as tetraphosphorus decaoxide (P₄O₁₀), tetraphosphorus octoxide (P₄O₈), and tetraphosphorus hexaoxide (P₄O₆). The tetraphosphorus decaoxide is sometimes called diphosphorus pentoxide (P₂O₅). The phosphorus containing molecule may be a halide (phosphorus halide), such as phosphorus trifluoride (PF₃), phosphorus pentafluoride (PF₅), phosphorus trichloride (PCl₃), phosphorus pentachloride (PCl₅), phosphorus tribromide (PBr₃), phosphorus pentabromide (PBr₅), and phosphorus iodide (PI₃). That is, the phosphorus containing molecule may contain fluorine as a halogen element such as phosphorus fluoride. Alternatively, the phosphorus containing molecule may contain a halogen element other than fluorine, as a halogen element. The phosphorus containing molecule may be halogenated phosphoryl, such as phosphoryl fluoride (POF₃), phosphoryl chloride (POCl₃), and phosphoryl bromide (POBr₃). The phosphorus containing molecule may be phosphine (PH₃), calcium phosphide (such as Ca₃P₂), phosphoric acid (H₃PO₄), sodium phosphate (Na₃PO₄), hexafluorophosphoric acid (HPF₆), or the like. The phosphorus containing molecule may be fluorophosphines (HₓPF_{y}). Here, the sum of x and y is 3 or 5. As the fluorophosphine, HPF₂ and H₂PF₃ are exemplified. The processing gas may contain one or more phosphorus containing molecules among the phosphorus containing molecules described above, as at least one phosphorus containing molecule. For example, the processing gas may contain at least one of PF₃, PCl₃, PF₅, PCl₅, POCl₃, PH₃, PBr₃, or PBr₅ as at least one phosphorus containing molecule. When each phosphorus containing molecule contained in the processing gas is a liquid or a solid, each phosphorus containing molecule may be evaporated by heating or the like and supplied into the chamber 10.

The processing gas used in step ST2 may further contain carbon and hydrogen. The processing gas may contain at least one of H₂, hydrocarbon (CₓH_{y}), hydrofluorocarbon (CₓH_{y}F_{z}), or an NH₃ as the hydrogen containing molecule. The hydrocarbon is, for example, CH₄ or C₃H₆. Here, each of x and y is a natural number. The processing gas may contain fluorocarbon or hydrocarbon (for example, CH₄) as carbon containing molecules. The processing gas may further contain oxygen. The processing gas may contain, for example, O₂. Alternatively, the processing gas may not contain oxygen.

The processing gas used in step ST2 may include a phosphorus containing gas, a fluorine containing gas, and a hydrogen containing gas containing at least one selected from the group consisting of hydrogen fluoride, hydrogen (H₂), ammonia, and a hydrocarbon. The fluorine containing gas may be fluorocarbon and/or hydrofluorocarbon. Further, the processing gas may be a halogen containing gas containing a halogen element other than a phosphorus containing gas, a fluorine containing gas, a hydrofluorocarbon gas, and fluorine. The fluorine containing gas is, for example, a nitrogen trifluoride gas (NF₃ gas) or a sulfur hexafluoride gas (SF6 gas).

In step ST2, the pressure of the gas within the chamber 10 is set to a designated pressure. In step ST2, the pressure of the gas within the chamber 10 may be set to a pressure of 10 mTorr (1.3 Pa) or more and 100 mTorr (13.3 Pa) or less. Further, in step ST2, the first radio-frequency power and/or the second radio-frequency power are supplied to generate plasma from the processing gas within the chamber 10. The level of the first radio-frequency power may be set to a level of 2 kW or more and 10 kW or less. The level of the second radio-frequency power may be set to a level of 2 kW (2.83 W/cm² in the level of the power per unit area of the substrate W) or more. The level of the second radio-frequency power may be set to a level of 10 kW (14.2 W/cm² in the level of the power per unit area of the substrate W) or more.

In an embodiment, the temperature of the substrate W at the start of step ST2 may be set to a temperature of 20° C. or lower, for example, 0° C. or lower, and −40° C. or −70° C. in an example. In order to set the temperature of the substrate W at the start of step ST2, the controller 80 may control the pressure of the heat transfer gas (for example, He) between the chiller unit, the electrostatic chuck, and the back surface of the substrate.

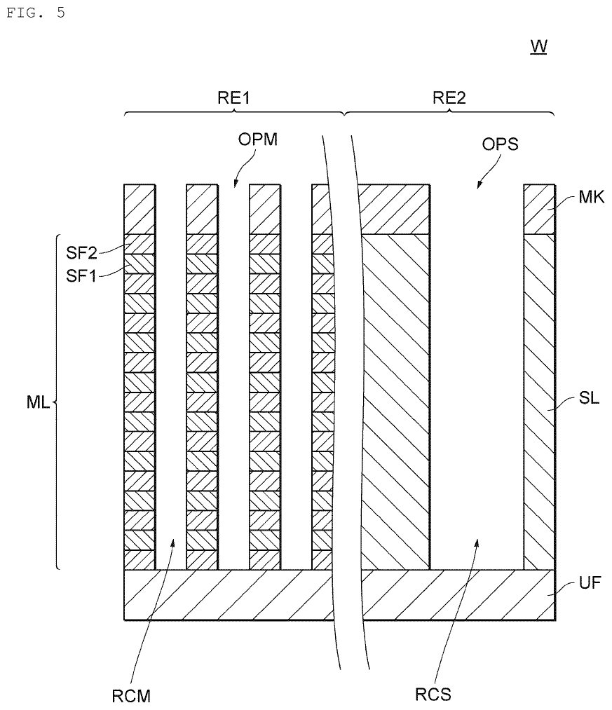

In step ST2, the multilayer film ML and the monolayer film SL are etched at the same time by a chemical species from plasma formed from the processing gas (see FIG. 5). Specifically, a portion of the multilayer film ML exposed in the opening OPM is etched, and a recess RCM is continuously formed in the multilayer film ML from the mask film MK based on the shape of the opening OPM of the mask film MK. Further, a portion of the monolayer film SL exposed in the opening OPS is etched, and a recess RCS is continuously formed in the monolayer film SL from the mask film MK based on the shape of the opening OPS of the mask film MK.

As an example, the method of forming recesses by etching the multilayer film ML and the monolayer film SL at the same time by using the mask film MK having the opening pattern shown in FIG. 3 has been described above, but the recesses corresponding to the opening pattern shown in FIG. 3 may be formed separately a plurality of times. For example, after the recesses corresponding to a part of the portions of the plurality of openings illustrated in FIG. 3 are formed by steps ST1 and ST2 described above, the recesses corresponding to the rest of the plurality of openings may be formed by steps ST3 and ST4 described below. Hereinafter, examples of such steps ST3 and ST4 will be described.

### (Step ST3: Preparation of Substrate W)

After step ST2 and the other steps, in step ST3, the same step as step ST1 is executed on the substrate W. As an example, when the substrate W is a substrate on which a 3D NAND flash memory is to be formed, the other step is, for example, a step of forming a memory cell in a recess (opening) formed in the multilayer film ML in step ST2.

The substrate W prepared in step ST3 includes a mask film MK. The mask film MK has a pattern different from the mask film MK prepared in step ST1. In the mask film MK prepared in step ST1, the first region RE1 has one or more openings OPM, and the second region RE2 has one or more openings OPS. Meanwhile, the mask film MK prepared in step ST3 has one or more openings OPM and/or OPS in at least one of the first region RE1 and the second region RE2.

As an example, when the substrate W is a substrate on which a 3D NAND flash memory is to be formed, the first region RE1 may be, for example, a memory cell region in which a memory cell is formed. Further, in an example, the second region RE2 may be a contact region where a contact for electrically connecting the memory cell and the peripheral circuit is formed. In an example, the opening OPM may be an opening (in an example, opening OPM1) for forming a memory hole in which a memory cell is to be formed in the multilayer film ML. Further, in an example, the opening OPS may be an opening (in an example, opening OPS1) for forming a contact hole in the monolayer film SL. Further, in an example, the opening OPM may be an opening (in an example, opening OPM2) for forming a slit in the multilayer film ML in the memory cell region. The slit may be a slit provided from the memory cell region to the contact region. In this case, the opening OPS may be an opening (for example, opening OPS2) for forming a slit in the monolayer film SL.

(Step ST4: Etching of Multilayer Film ML and/or Monolayer Film SL)

Next, in step ST4, the multilayer film ML and/or the monolayer film SL are etched by using the mask film MK prepared in step ST3. Step ST4 is an example of the second etching step. In step ST4, the multilayer film ML and the monolayer film SL may be etched under the same conditions as those in step ST2, or may be etched under different conditions. In an example, in step ST4, the processing gas for etching the multilayer film ML and/or the monolayer film SL may include a phosphorus containing gas, similarly to step ST2. The phosphorus containing gas used in step ST4 may be the same type (substance) of gas as the phosphorus containing gas used in step ST2, or may be a different type (substance) of gas. Further, in step ST2 and step ST4, the phosphorus containing gas may be supplied to the chamber 10 at the same flow rate, or may be supplied at different flow rates. The type and/or flow rate of the phosphorus containing gas used in step ST4 may be appropriately selected, for example, according to the film to be etched (such as multilayer film or monolayer film), the opening OPM, and/or the opening width of the opening OPS.

### Examples

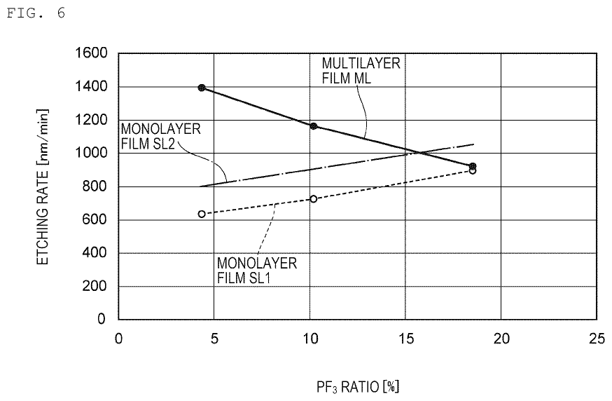

Hereinafter, a test performed for the evaluation of the present etching method will be described. In the present test, as the processing gases, O₂, C₄F₆H₂, HF, and PF₃ were used. Further, changes in the etching rates of the multilayer film ML and the monolayer film SL were confirmed by changing the flow rate of PF₃. Further, the ratio of the flow rate of PF₃ to the processing gas is in a range of 4% to 19%. Further, the ratio of the flow rate of HF in the processing gas is 50% or more. Further, the solid line in FIG. 6 represents the etching rate of the multilayer film ML when the opening width of the mask film MK is 100 nm. Further, the broken line in FIG. 6 represents the etching rate of the monolayer film SL (hereinafter, referred to as a “monolayer film SL1”) when the opening width of the mask film MK is 100 nm. Further, the one-dot chain line in FIG. 6 represents an assumed etching rate of the monolayer film SL (hereinafter, referred to as a “monolayer film SL2”) when the opening width of the mask film MK is about 150 nm. The multilayer film ML is a stacked film of a silicon oxide film and a silicon nitride film. Further, the monolayer film SL is a silicon oxide film. Further, the temperature of the substrate W was set to −70° C.

FIG. 6 is a graph showing the relationship between the flow rate of PF₃ and the etching rates of the multilayer film ML, a monolayer film SL1, and a monolayer film SL2. As shown in FIG. 6, it was confirmed that the ratio of the etching rate of the monolayer film SL to the etching rate of the multilayer film ML can be controlled by controlling the flow rate of the phosphorus containing gas, such as making the etching rates of the multilayer film ML and the monolayer film SL close to each other when the multilayer film ML and the monolayer film SL are etched at the same time. That is, as shown in FIG. 6, it was confirmed that the etching rate of the monolayer film SL was lower than the etching rate of the multilayer film ML in the region where the flow rate of PF₃ was small (the region where the flow rate ratio of PF₃ in the processing gas was low). On the other hand, it was confirmed that in the region where the flow rate of PF₃ was high (the region where the flow rate ratio of PF₃ in the processing gas was high), the ratio of the etching rate of the monolayer film SL to the etching rate of the multilayer film ML was made close to 1. In a state where the phosphorus chemical species generated from the plasma of the phosphorus containing gas (gas that contains the phosphorus containing molecule described above) was present on the surface of the silicon oxide film, the adsorption of hydrogen fluoride, that is, etchant, to the silicon oxide film is accelerated. As a result, phosphorus chemical species generated from the phosphorus containing gas were present on the surface of the silicon oxide film exposed at the bottom of the opening OPS of the mask film MK, and the supply of the etchant to the surface was accelerated so that the etching rate of the monolayer film SL was improved.

Further, the etching rates of the silicon oxide film and the silicon nitride film depend on the widths (diameters) of the openings OPM and OPS due to the micro loading effect. That is, the etching rates of the multilayer film ML and the monolayer film SL may differ depending on the recess widths (or the widths of the openings OPM and OPS) of the multilayer film ML and the monolayer film SL. In the present example, the ratio of the etching rate of the monolayer film SL to the etching rate of the multilayer film ML can be made 1 or more by making the recess width (the width of the opening OPM) of the monolayer film SL larger than the recess width (the width of the opening OPM) of the multilayer film ML and generating plasma from the processing gas that contains the phosphorus containing gas. In other words, even when the recess widths of the multilayer film ML and the monolayer film SL are different, the etching rates of the multilayer film ML and the monolayer film SL can be controlled by controlling the flow rate of the phosphorus containing gas. For example, the etching rate of the monolayer film SL2 can be made to be substantially the same as the etching rate of the multilayer film ML at a flow rate lower than that of the monolayer film SL1 in terms of PF₃.

The above embodiments are described for the purpose of illustration, and various modifications may be made without departing from the scope and idea of the present disclosure. For example, in addition to the capacitively-coupled plasma processing apparatus 1, a substrate processing apparatus using any plasma source such as inductively-coupled plasma or microwave plasma may be used.

### REFERENCE SIGNS LIST

1: plasma processing apparatus, 10: chamber, 10s: internal space, 12: chamber body, 13: support, 14: substrate support, 16: electrode plate, 18: lower electrode, 20: electrostatic chuck, 24: gas supply line, 25: edge ring, 30: upper electrode, 32: member, 34: ceiling plate, 36: support body, 38: gas supply pipe, 40: gas source group, 41: flow rate controller group, 42: valve group, 46: shield, 48: baffle plate, 50: exhaust device, 52: exhaust pipe, 62: radio-frequency power supply, 64: bias power supply, 66: matcher, 68: matcher, 80: controller, MK: mask film, ML: multilayer film, OPM: opening, OPS: opening, RCM: recess, RCS: recess, RE1: first region, RE2: second region, SF1: silicon nitride film, SF2: silicon oxide film, SL: monolayer film, UF: underlying film, W: substrate

1. An etching method comprising:
preparing a substrate having a first region and a second region, the substrate including a multilayer film in which two or more types of silicon containing films are stacked in the first region, and a monolayer film formed from one type of silicon containing film in the second region; and
etching the multilayer film and the monolayer film at the same time, wherein
in the etching,
the multilayer film and the monolayer film are etched at the same time by plasma generated from a processing gas that contains a hydrogen fluoride gas, a phosphorus containing gas, and a carbon containing gas,
a first recess having a first width is formed in the multilayer film, and
a second recess having a second width wider than the first width is formed in the monolayer film.

2. An etching method comprising:
preparing a substrate having a first region and a second region, the substrate including a multilayer film in which two or more types of silicon containing films are stacked in the first region, and a monolayer film formed from one type of silicon containing film in the second region; and
etching the multilayer film and the monolayer film at the same time, wherein
in the etching,
the multilayer film and the monolayer film are etched by plasma generated from a processing gas that contains a hydrogen fluoride gas, a phosphorus containing gas, and a carbon containing gas,
a first recess is formed in the multilayer film, and
a second recess is formed in the monolayer film.

3. An etching method comprising:
preparing a substrate having a first region and a second region, the substrate including a multilayer film in which two or more types of silicon containing films are stacked in the first region, and a monolayer film formed from one type of silicon containing film in the second region; and
etching the multilayer film and the monolayer film at the same time, wherein
in the etching,
the multilayer film and the monolayer film are etched by plasma generated from a processing gas that contains a phosphorus containing gas, a fluorine containing gas, a hydrofluorocarbon gas, and a halogen containing gas that contains a halogen element other than fluorine,
a first recess having a first width is formed in the multilayer film, and
a second recess having a second width wider than the first width is formed in the monolayer film.

4. An etching method comprising:
preparing a substrate having a first region and a second region, the substrate including a multilayer film in which two or more types of silicon containing films are stacked in the first region, and a monolayer film formed from one type of silicon containing film in the second region; and
etching the multilayer film and the monolayer film at the same time, wherein
in the etching,
the multilayer film and the monolayer film are etched by plasma generated from a processing gas that contains a phosphorus containing gas, a fluorine containing gas, a hydrofluorocarbon gas, and a halogen containing gas that contains a halogen element other than fluorine,
a first recess is formed in the multilayer film, and
a second recess is formed in the monolayer film.

5. The etching method according to claim 1, wherein
the substrate includes a mask film provided on the multilayer film and the monolayer film, the mask film having a first side wall defining a first opening on the multilayer film, and a second side wall defining a second opening on the monolayer film, and
in the etching,
the first recess is formed by etching the multilayer film with the plasma in the first opening, and
the second recess is formed by etching the monolayer film with the plasma in the second opening.

6. The etching method according to claim 1, wherein
one of the first recess and the second recess is a hole, and
the other of the first recess and the second recess is a slit.

7. The etching method according to claim 1, wherein
the two or more types of silicon containing films include a silicon oxide film and a silicon nitride film, and
the one type of silicon containing film is a silicon oxide film.

8. The etching method according to claim 1, wherein
the phosphorus containing gas is a halogenated phosphorus gas.

9. The etching method according to claim 1, wherein
the carbon containing gas is a hydrocarbon gas, a fluorocarbon gas, or a hydrofluorocarbon gas.

10. An etching method comprising:
preparing a substrate having a first region and a second region, the substrate including a multilayer film in which two or more types of silicon containing films are stacked in the first region, and a monolayer film formed from one type of silicon containing film in the second region;
first etching the multilayer film and the monolayer film at the same time; and
second etching at least one of the multilayer film and the monolayer film, wherein
in the first etching,
the multilayer film and the monolayer film are etched by plasma generated from a first processing gas that contains a hydrogen fluoride gas and a phosphorus containing gas,
a first recess is formed in the multilayer film, and
a second recess is formed in the monolayer film, and
in the second etching,
the multilayer film and the monolayer film are etched by plasma generated from a second processing gas that contains a hydrogen fluoride gas and a phosphorus containing gas,
a third recess is formed in at least one of the multilayer film and the monolayer film, and
a flow rate of the phosphorus containing gas contained in the first processing gas is different from a flow rate of the phosphorus containing gas contained in the second processing gas.

11. The etching method according to claim 10, wherein
the second etching is executed after the first etching is executed.

12. The etching method according to claim 10, wherein
the first etching is executed after the second etching is executed.

13. The etching method according to claim 10, wherein
the substrate is a substrate on which a plurality of semiconductor storage devices are formed,
the first region is a region where a plurality of memory cells are formed in each of the plurality of semiconductor storage devices, and
the second region is a region where a plurality of contacts that electrically connect the plurality of memory cells and a circuit that controls the plurality of memory cells are formed in each of the plurality of semiconductor storage devices.

14. The etching method according to claim 13, wherein
in the first etching,
a plurality of memory holes in which the plurality of memory cells are formed are formed in the multilayer film as first recesses, and
a plurality of contact holes in which the plurality of contacts are formed are formed in the monolayer film as second recesses, and
in the second etching,
slits extending from the first region to the second region are formed in the multilayer film and the monolayer film as third recesses.

15. The etching method according to claim 13, wherein
in the first etching,
a plurality of memory holes in which the plurality of memory cells are formed are formed in the multilayer film as first recesses, and
slits extending from the first region to the second region are formed in the multilayer film and the monolayer film as the first recess and the second recess above, and
in the second etching,
a plurality of contact holes in which the plurality of contacts are formed are formed in the monolayer film as second recesses.

16. The etching method according to claim 13, wherein
in the first etching,
a plurality of contact holes in which the plurality of contacts are formed are formed in the monolayer film as second recesses, and
slits extending from the first region to the second region are formed in the multilayer film and the monolayer film as the first recess and the second recess, and
in the second etching,
a plurality of memory holes in which the plurality of memory cells are formed are formed in the multilayer film as first recesses.

17. The etching method according to claim 13, wherein
in the first etching,
slits extending from the first region to the second region are formed in the multilayer film and the monolayer film as the first recess and the second recess, and
in the second etching,
a plurality of memory holes in which the plurality of memory cells are formed are formed in the multilayer film as first recesses, and
a plurality of contact holes in which the plurality of contacts are formed are formed in the monolayer film as second recesses.
